(19) United States
(12) Patent Application Publication
(10) Pub. No.: US 2025/0038121 A1
(43) Pub. Date: Jan. 30, 2025

(54) Manufacturing method of a system in package having several layers and associated manufacturing installation

(71) Applicant: THALES, Meudon (FR)

(72) Inventors: Damien CHALAVOUX, VALENCE CEDEX (FR); Pierre ELOI, VALENCE CEDEX (FR); Maxime REY, VALENCE CEDEX (FR)

(21) Appl. No.: 18/716,457

(22) PCT Filed: Dec. 9, 2022
(86) PCT No.: PCT/EP2022/085203

§ 371 Date: Jun. 13, 2024

(30) Foreign Application Priority Data
Dec. 10, 2021 (FR) FR2113285

(51) Int. Cl. H01L 23/538; H01L 21/02; H01L 23/00; H01L 23/29; H01L 23/36; H01L 25/10

(52) U.S. Cl. CPC H01L 23/5389; H01L 21/02422; H01L 23/295; H01L 23/36; H01L 24/27; H01L 25/105; H01L 2224/2731; H01L 2224/27848; H01L 2224/27901; H01L 2924/15153

(57) ABSTRACT

The present invention relates to a method for manufacturing a system in package having several layers, including for each current layer realization of a dielectric substrate by an additive manufacturing technique, deposition of an adhesive in receiving zones, deposition of electronic components in the corresponding receiving zones, deposition of interconnection elements between the electronic components, creation of at least one interconnection with an adjacent layer, encapsulation of the current layer with filler material, the filler material forming an outer surface, and preparation of the outer surface for receiving the next layer.

### CROSS-REFERENCE TO RELATED APPLICATIONS

This application claims benefit under 35 USC § 371 of PCT Application No. PCT/EP2022/0852043 entitled PROCESS FOR MANUFACTURING A SYSTEM IN PACKAGE HAVING A PLURALITY OF LAYERS AND ASSOCIATED MANUFACTURING APPARATUS, filed on Dec. 9, 2022 by inventors Damien Chalavoux, Pierre Eloi and Maxime Rey. PCT Application No. PCT/EP2022/085203 claims priority of French Patent Application No. 21 13285, filed on Dec. 10, 2021.

### FIELD OF THE INVENTION

The present invention relates to a method of manufacturing a system in a package having several layers.

The present invention also relates to a manufacturing installation associated with such a manufacturing process.

### BACKGROUND OF THE INVENTION

For the purposes of the present invention, the term “system in a package” refers to any system more commonly referred to as a SIP (System in Package). Such a system is also known as a System-in-a-Package or Multi-Chip Module (MCM).

As is well known, a SiP is a system of integrated circuits that are confined in a single package. This type of system is widely used in the field of microelectronics and particularly in the fields of mobile telephony, computers, sensors, etc. In some cases, a SiP can comprise a stack of layers which makes it particularly compact and thus attractive for this type of application.

Generally, the realization of a SiP requires strong investments in u-technology machines to assemble chips in three dimensions and thus compact the electronic functions in a block or package rather than on a flat surface.

These blocks are intended to be assembled on a printed circuit board (PCB) so that they can be interconnected with other blocks or other discrete components. The external connections are made, for example, by metallization in chemical deposition baths.

Several methods in the state of the art are intended to simplify the manufacture of a SiP or at least to make this manufacture more universal so that different SiPs can be produced.

Thus, for example, methods are known to make the design of a SiP more flexible. According to some of these methods, the substrate on which the different electronic components are placed, present an interconnection matrix. This matrix presents a large number of possible interconnections which are then chosen according to the electronic components placed and the needs of their interconnection.

There are also methods of miniaturization of the boards. Among these methods, the method known as Flip Chip proposes, at the last stage of production, to turn the chip upside down and to deposit solder bumps on the flip surface of the chip. In order to be connected to the other components, the chip is turned upside down, its legs are placed opposite the corresponding legs of the substrate and are heated to be integral with the rest of the substrate. This method is therefore opposed to a wire bonding method according to which the interconnections between the chips and the substrate are made by wires.

Among the methods of miniaturization of the cards, is also known the method known under the name of Wafer-Level Packaging (WLP) according to which one encapsulates the chips which are always solid the one from the others, then the balls of solder are added, and only afterward is the plate cut to separate the chips. The encapsulated chip has the same surface as the chip alone, which allows to save space occupied on the circuit relative to a traditional manufacturing method.

Finally, there are also 3D stacking methods allowing to manufacture the SiPs in multiple layers. For example, the method known as 3D integrated circuit (3D IC) allows to stack several chips. The interconnections are most often made by a Through-Silicon Vias (TSV), which connects the chips from the inside, unlike techniques that connect the chips from the outside, for example by using wires.

Current SiP manufacturing methods therefore require expensive facilities that are difficult to adapt to the manufacture of other types of SiP and/or other types of electronic components. Therefore, these methods cannot be used to manufacture SiPs for series of thousands of parts.

### SUMMARY OF THE DESCRIPTION

To this end, the invention has as its object a method for manufacturing a system in a multi-layer package comprising for each current layer the following steps:
making a dielectric substrate by an additive manufacturing technique, the substrate comprising a receiving surface, the receiving surface comprising receiving zones configured to receive electronic components;
depositing an adhesive in the receiving zones; and
depositing electronic components in the corresponding receiving zones;
depositing interconnection elements between the electronic components;
creation of at least one interconnection with an adjacent layer;
encapsulating the current layer with filler material, the filler material forming an outer surface; and
preparing the outer surface for receiving the next layer.

The manufacturing method according to the invention thus allows the use of a single installation for all manufacturing steps. In addition, an additive manufacturing technique implemented by this method allows a variety of SiPs to be manufactured without any changes between each series produced, making the unit cost of each SiP very competitive.

According to other advantageous aspects of the invention, the method comprises one or more of the following features, taken alone or in any technically possible combination:
the step of making the dielectric substrate comprises polymerizing it, preferably photopolymerizing it;
the additive manufacturing technique comprises the stereolithography technique or the molten wire deposition technique;
the step of depositing the adhesive is carried out by an endless screw or by a time pressure distribution system;
the step of depositing the electronic components is carried out by a deposition head, preferably, the step of depositing the electronic components further comprises the placement of heat sinks bonded to the electronic components;
the method further comprising a step of polymerization of the adhesive implemented after the step of depositing the electronic components and before the step of depositing interconnection elements;
the step of depositing interconnection elements comprises the deposition of conductive wires or a conductive ink between electronic components;
the step of creating at least one interconnection with an adjacent layer comprises depositing a conductive adhesive or a plastic loaded with conductive particles;
the step of encapsulating the current layer comprises filling a volume delimited by the dielectric substrate with the filler material;
the step of preparing the outer surface comprises implementing a stripping technique;
the method further comprising an optical inspection step implemented between at least some of said steps.

The present invention also has as its object an installation for manufacturing a system in package (SiP), having several layers, the installation comprising a plurality of modules able to implement the method as previously described.

### BRIEF DESCRIPTION OF THE DRAWINGS

These features and advantages of the invention will become apparent from the following description, given only as a non-limiting example, and made with reference to the appended drawings, in which:

FIG. 1 is a schematic view of a manufacturing installation according to the invention; and

FIG. 2 is a schematic view of the implementation of various steps of a manufacturing method according to the invention, the method being implemented by the installation of FIG. 1.

### DETAILED DESCRIPTION OF EMBODIMENTS

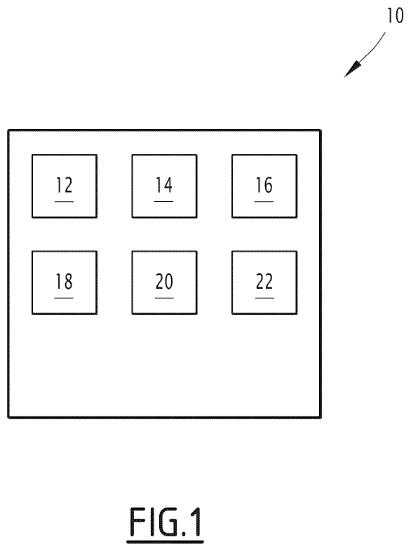

Indeed, a manufacturing installation 10 for a system in a package, known as a SiP, was illustrated in FIG. 1. In particular, such a manufacturing installation 10 allows for the production of multi-layered SiPs of different types.

To this end, with reference to FIG. 1, the manufacturing installation 10 includes an additive manufacturing module 12, a chip bonding module 14, a deposition module 16, an interconnection module 18, an encapsulation module 20, and a stripping module 22.

According to various embodiments of the manufacturing method, the manufacturing installation 10 may comprise other functional modules at least partially implementing at least some of the steps of this method. For example, the manufacturing installation 10 may further comprise a heating module and/or a control module allowing to control the deposition or placement of components.

The manufacturing installation 10 also comprises mechanical means implementing the operation of these various modules 12 to 22, their interconnection as well as their connection to external sources.

Finally, the manufacturing installation 10 also comprises a base able to receive the SiP after its manufacture. In particular, each SiP can be produced on this base by turning on the aforementioned modules 12 to 22, in accordance with the manufacturing method explained below.

The additive manufacturing module 12 presents a 3D printing machine able to implement an additive manufacturing technique to produce a dielectric substrate. The additive manufacturing technique comprises, for example, the stereolithography technique or the molten wire deposition technique. This latter technique is also known by the acronym FDM (Fused Deposition Modeling). Thus, for example, this module 12 can operate by depositing the ink in the form of fine droplets, layer by layer.

The chip bonding module 14 comprises, for example, a machine known as a Die Bonding machine. Such a machine may, for example, comprise a robot for depositing adhesive by means of an endless screw or a time-pressure distribution system. In particular, such a dispensing system allows to obtain a drop of adhesive of a repeatable size by controlling the pressure put into a syringe in which the adhesive is located. By varying the pressure time, the size of the adhesive drop can be controlled (larger or smaller).

The deposition module 16 comprises, for example, a volumetric deposition head able to take an electronic component and place it on a substrate. Such a head can be realized by a machine known as Pick and Place or can be part of the Die Bonding machine mentioned above.

The interconnection module 18 comprises, for example, a Wire Bonding machine configured to connect different electronic components using a wire. Alternatively, the interconnect module 18 comprises a machine for depositing a conductive ink. Such a machine can, for example, be adapted to implement the flip chip technique.

The encapsulation module 20 comprises, for example, a Dam and Fill machine allowing to fill a structure with a filling material.

Finally, the stripping module 22 comprises a stripping head for stripping a surface using, for example, a plasma.

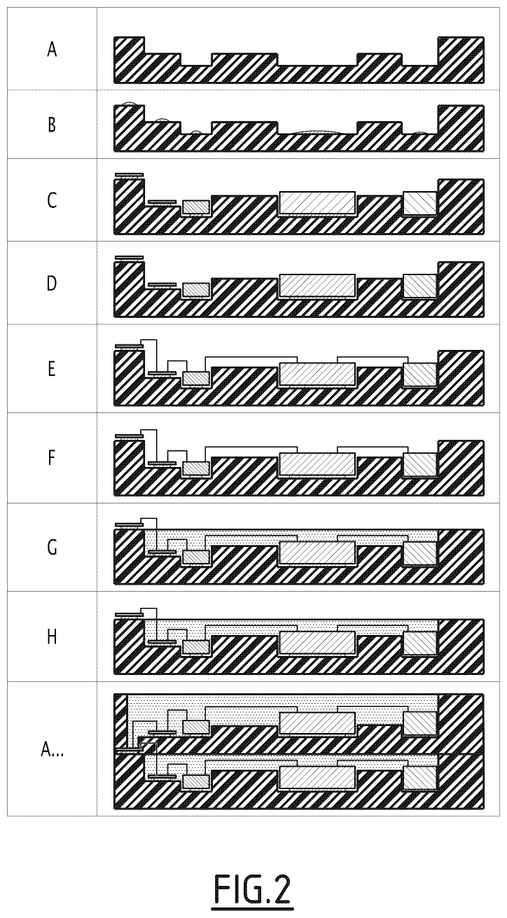

The method for manufacturing a SiP implemented by the manufacturing installation 10 will now be explained with reference to FIG. 2.

The steps of this method are implemented consecutively for each layer forming the SiP.

In some embodiments, between each step explained below or at least between some of these steps, a control step may be implemented in which the imaging control module may be used to control the deposits or the placement and direction of the components.

During an initial step A, the additive manufacturing module 12 realizes a dielectric substrate by implementing an additive manufacturing technique, as explained above. This substrate is realized directly on the base when it is a first layer of the SiP or on a stripped surface of another layer when it is an intermediate or final layer.

The substrate formed during this step comprises a receiving surface comprising receiving zones configured to receive the electronic components.

In particular, each receiving zone presents, for example, a cavity, the dimensions of which are able to receive a given electronic component. The locations of the receiving zones as well as their dimensions are determined, for example, in accordance with a configuration file specific to, for example, each layer. In other words, such a configuration file forms a “map” of each layer. The additive manufacturing module 12 is thus able to read such a file and deposit layers in accordance with that file.

The formed substrate may further comprise a wall extending along the periphery of the substrate and forming a portion of the lateral surface of the SiP. Such a wall may further delineate an internal volume of the substrate receiving the electrical components as well as the filler material as will be explained later.

The dielectric substrate may be deposited on a printed circuit type substrate.

At the end of step A, the dielectric substrate may be cured, preferably by photopolymerization, to acquire its final properties.

During step B, the chip attachment module 14 deposits an adhesive in the receiving zones formed in the substrate. The adhesive can, for example, be selected to have a low expansion or at least an expansion adapted to the substrate.

During step C, the deposition module 16 deposits the electronic components in the corresponding receiving zones. By electronic component is meant, in particular, a chip or any other electronic element forming part of a SiP.

This step C may also comprise the placement of heat sinks, for example of a solid type (copper substrate, heat pipes), bonded to the electronic components.

During step D, the adhesive is cured. This polymerization is carried out, for example, by a heating module that implements local or global heating. Alternatively, the polymerization is carried out at room temperature, without heating.

During step E, the interconnection module 18 deposits interconnection elements between the electronic components. The interconnection elements may then comprise conductive wires or conductive ink.

During step F, the interconnection module 18 creates an interconnection with at least one upper or lower layer, for example with conductive adhesive with a module for depositing an adhesive (syringes with adhesive) or a plastic, for example light-curing polymer, loaded with metal particles and this deposited with the additive manufacturing module 12.

During step G, the encapsulation module 20 encapsulates the current layer by, for example, filling the volume, delimited by the substrate walls, to the same level as these walls. After filling, the filler material then forms an outer surface.

During step H, the stripping module 22 prepares the outer surface for receiving the next layer. In particular, as explained above, this step may include stripping the outer surface.

Then, when a subsequent layer is to be created, steps A to H are thus implemented again.

Of course, other embodiments of the invention are also possible.

1. A method for manufacturing a system in package having several layers, the method comprising for each current layer:
realizing a dielectric substrate by an additive manufacturing technique, the substrate comprising a receiving surface, the receiving surface comprising receiving zones configured to receive electronic components;
depositing an adhesive in the receiving zones;
depositing electronic components in the corresponding receiving zones;
depositing interconnecting elements between the electronic components;
creating at least one interconnection with an adjacent layer;
encapsulating the current layer with filler material, the filler material forming an outer surface; and
preparing the outer surface to receive the next layer.

2. The method according to claim 1, wherein said realizing comprises realizing a polymerization of the dielectric substrate.

3. The method according to claim 1, wherein the additive manufacturing technique comprises a stereolithography technique or a molten wire deposition technique.

4. The method according to claim 1, wherein said depositing an adhesive is performed by an endless screw or by a time pressure dispensing system.

5. The method according to claim 1, wherein said depositing electronic components is performed by a deposition head.

6. The method according to claim 1, further comprising polymerizing the adhesive after said depositing electronic components and before said depositing interconnecting elements.

7. The method according to claim 1, wherein said depositing interconnecting elements comprises depositing conductive wires or a conductive ink between the electronic components.

8. The method according to claim 1, wherein said creating comprises depositing a conductive adhesive or a plastic loaded with conductive particles.

9. The method according to claim 1, wherein said encapsulating comprises filling a volume delimited by the dielectric substrate with the filler material.

10. The method according to claim 1, wherein said preparing comprises implementing a stripping technique.

11. The method according to claim 1, further comprising optically inspecting.

12. A manufacturing installation for a system in a multi-layer package, the installation comprising a plurality of modules implementing the method according to claim 1.

13. The method according to claim 2, wherein said realizing comprises realizing a photopolymerization of the dielectric substrate.

14. The method according to claim 5 wherein said depositing electronic components further comprises placing heat sinks bonded to the electronic components.
